(19) United States
(12) Patent Application Publication
(10) Pub. No.: US 2026/0122782 A1
(43) Pub. Date: Apr. 30, 2026

(54) PRINTED CIRCUIT BOARD

(71) Applicant: SAMSUNG ELECTRO-MECHANICS CO., LTD., Suwon-si (KR)

(72) Inventors: Myoung Hoon KIM, Suwon-si (KR); Seok Hwan KIM, Suwon-si (KR); Geon Hui PARK, Suwon-si (KR)

(73) Assignee: SAMSUNG ELECTRO-MECHANICS CO., LTD., Suwon-si (KR)

(21) Appl. No.: 19/057,329

(22) Filed: Feb. 19, 2025

(30) Foreign Application Priority Data
Oct. 28, 2024 (KR) 10-2024-0148841

(51) Int. Cl. H05K 1/11; H05K 1/02; H05K 1/03

(52) U.S. Cl. CPC H05K 1/115; H05K 1/0203; H05K 1/0306; H05K 2201/10416

(57) ABSTRACT

The present disclosure relates to a printed circuit board comprising a glass layer with a first surface and a second surface opposing each other in a first direction. A heat dissipation member is embedded in the glass layer, and a through-via extends through at least a portion of the glass layer between the first and second surfaces. The heat dissipation member may be spaced apart from one or both surfaces of the glass layer.

### CROSS-REFERENCE TO RELATED APPLICATION(S)

This application claims benefit of priority to Korean Patent Application No. 10-2024-0148841 filed on Oct. 28, 2024, in the Korean Intellectual Property Office, the disclosure of which is incorporated herein by reference in its entirety.

### TECHNICAL FIELD

The present disclosure relates to a printed circuit board.

Recently, in order to improve the performance of a package substrate, a large area, a multilayer, and miniaturization are required. Meanwhile, Copper Clad Laminate (CCL) is usually used as a core layer included in the package substrate. However, in the case of the CCL, warpage is likely to occur due to a low modulus and a high coefficient of thermal expansion, and there are also limitations in implementing microcircuits. Furthermore, as semiconductor products become more sophisticated, power consumption has increased, which may cause a thermal issue in products and substrates.

### SUMMARY

An aspect of the present disclosure is to provide a printed circuit board including a core layer that may suppress warpage and facilitates microcircuit implementation.

Another aspect of the present disclosure is to provide a printed circuit board including a core layer having excellent heat dissipation characteristics.

One of the various solutions proposed in the present disclosure is to use a glass layer as a core layer, which has a high modulus and a low coefficient of thermal expansion to suppress warpage and also has a smooth surface, making it easy to implement microcircuits.

Another solution proposed in the present disclosure is to embed a heat dissipation member that may directly contact the glass layer without a micro gap.

For example, a printed circuit board of the present disclosure may include: a glass layer having a first surface and a second surface opposing each other in a first direction; a heat dissipation member embedded in the glass layer; and a through-via penetrating through at least a portion between the first surface and the second surface of the glass layer, and the heat dissipation member may be spaced apart from one or more of the first surface and the second surface of the glass layer.

For example, a printed circuit board may include: a glass layer having a first surface and a second surface opposing each other in a first direction; a plurality of heat dissipation members respectively embedded in the glass layer, and respectively having a length in a second direction, perpendicular to the first direction, longer than a length in the first direction, in a cross-section in the first direction and the second direction; and a plurality of through-vias penetrating through at least a portion between the first surface and the second surface of the glass layer, and respectively spaced apart from the plurality of heat dissipation members.

One of the various effects of the present disclosure to provide a printed circuit board that may suppress warpage, and includes a core layer that may easily implement a microcircuit.

Another of the various effects of the present disclosure is to provide a printed circuit board including a core layer having excellent heat dissipation characteristics.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a block diagram schematically illustrating an example of an electronic device system;

FIG. 2 is a cross-sectional view schematically illustrating an example of a printed circuit board;

FIG. 3 is a process cross-sectional view schematically illustrating an example of manufacturing process for the printed circuit board of FIG. 2;

FIG. 4 is a cross-sectional view schematically illustrating a modified example of the printed circuit board of FIG. 2;

FIG. 5 is a cross-sectional view schematically illustrating another example of a printed circuit board;

FIG. 6 is a cross-sectional view schematically illustrating a modified example of the printed circuit board of FIG. 5; and

FIG. 7 is a graph schematically illustrating a heat radiation effect of the printed circuit board of FIG. 2 and the printed circuit board of FIG. 5.

### DETAILED DESCRIPTION

Hereinafter, the present disclosure will be described with reference to the accompanying drawings. In the drawings, the shape and size of the elements may be exaggerated or reduced for clearer description.

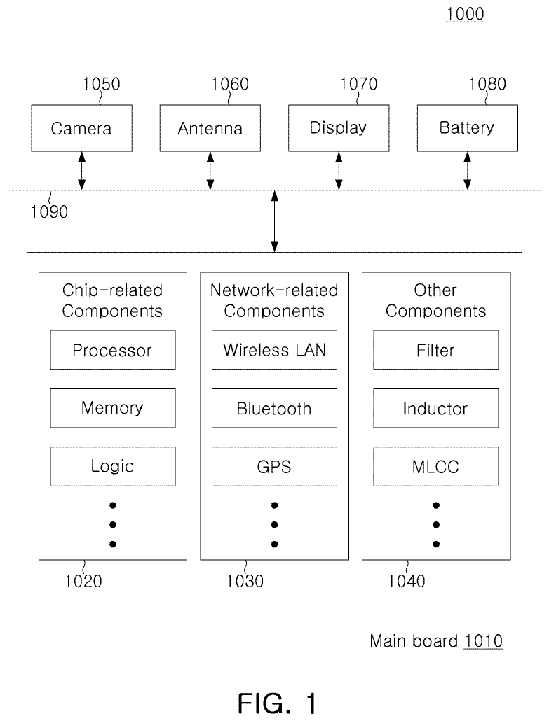

FIG. 1 is a block diagram schematically illustrating an example of an electronic device system.

Referring to FIG. 1, an electronic device 1000 accommodates a main board 1010 therein. Chip-related components 1020, network-related components 1030, and other components 1040 are physically and/or electrically connected to the main board 1010. These components are also coupled to other electronic components, described below, to form various signal lines 1090.

The chip-related components 1020 may include a memory chip such as a volatile memory (e.g., a DRAM), a non-volatile memory (e.g., a ROM), a flash memory, or the like; an application processor chip such as a central processor (e.g., a CPU), a graphics processor (e.g., a GPU), a digital signal processor, a cryptographic processor, a microprocessor, a microcontroller, or the like; and a logic chip such as an analog-to-digital (ADC) converter, an application-specific IC (ASIC), or the like. However, the chip-related components 1020 are not limited thereto, and may also include other types of chip-related electronic components. Furthermore, the chip-related components 1020 may be coupled to each other. The chip-related component 1020 may have the form of a package including the above-described chip or electronic component.

The network-related components 1030 may include wireless fidelity (Wi-Fi) (such as IEEE 802.11 family), worldwide interoperability for microwave access (WiMAX) (such as IEEE 802.16 family), IEEE 802.20, long term evolution (LTE), evolution data only (Ev-DO), HSPA+, HSDPA+, HSUPA+, EDGE, GSM, GPS, GPRS, CDMA, TDMA, DECT, Bluetooth, 3G, 4G, and 5G protocols, and any other wireless and wired standards or protocols specified thereafter. However, the network-related components 1030 are not limited thereto, and may also include any of a number of other wireless or wired standards or protocols. Furthermore, the network-related components 1030 may be coupled to the chip-related components 1020.

Other components 1040 may include a high frequency inductor, a ferrite inductor, a power inductor, ferrite beads, a low temperature co-firing ceramic (LTCC), an Electromagnetic Interference (EMI) filter, a Multilayer Ceramic Capacitor (MLCC), or the like. However, other components are not limited thereto, and may also include passive components in the form of chip components used for various other purposes. In addition, other components 1040 may be coupled to each other, together with the chip-related components 1020 and/or the network-related components 1030.

Depending on a type of electronic device 1000, the electronic device 1000 may include other electronic components that may or may not be physically and/or electrically connected to main board 1010. These other electronic components may include, for example, a camera module 1050, an antenna module 1060, a display 1070, and a battery 1080. However, these other electronic components are not limited thereto, but may also include an audio codec, a video codec, a power amplifier, a compass, an accelerometer, a gyroscope, a speaker, a mass storage device (e.g., a hard disk drive), a compact disk (CD), a digital versatile disk (DVD), or the like. In addition thereto, other electronic components used for various purposes depending on a type of electronic device 1000 may be included.

The electronic device 1000 may be a smartphone, a personal digital assistant, a digital video camera, a digital still camera, a network system, a computer, a monitor, a tablet PC, a laptop PC, a netbook PC, a television, a video game console, a smartwatch, an automotive component, or a server. However, the electronic device 1000 is not limited thereto and may be any other electronic device that processes data.

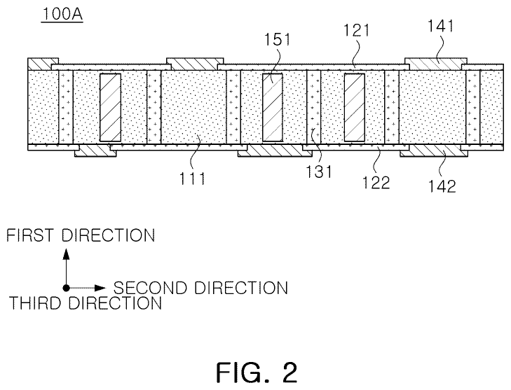

FIG. 2 is a perspective view schematically illustrating an example of an electronic device.

Referring to FIG. 2, a printed circuit board 100A according to an example embodiment may include a glass layer 111 having a first surface and a second surface opposing each other in a first direction, a heat dissipation member 151 embedded in the glass layer 111, and a through-via 131 penetrating at least a portion between the first surface and the second surface of the glass layer 111. If necessary, the printed circuit board 100A according to an example embodiment may further include a first wiring layer 121 disposed on the first surface of the glass layer 111, a second wiring layer 122 disposed on the second surface of the glass layer 111, a first resist layer 141 disposed on the first surface of the glass layer 111 and covering at least a portion of the first wiring layer 121 while exposing at least another portion thereof, and/or a second resist layer 142 disposed on the second surface of the glass layer 111 and covering at least a portion of the second wiring layer 122 while exposing at least another portion.

Meanwhile, as described above, CCL is usually used as a core layer included in a package substrate. However, recently, a large-area, a multilayer structure, and miniaturization are required for high performance of the package substrate, and there is a limit to satisfying these requirements when the CCL is included as a core layer. On the other hand, the printed circuit board 100A according to an example embodiment may have a high modulus and a low coefficient of thermal expansion, which may suppress warpage, and may also have a smooth surface to include the glass layer 111 that may easily implement microcircuits, as a core layer, and therefore, the printed circuit board 100A may have an advantageous effect as compared to a case in which the CCL is included as a core layer.

Additionally, as described above, as a semiconductor product is increasingly sophisticated, the power consumption has increases, and thermal issues of products and substrates have occurred. Accordingly, improvement of heat dissipation characteristics is required. Accordingly, it may be possible to consider forming a heat dissipation via in the glass layer by forming a Through Glass via (TGV), but it may be difficult to completely fill a metal without voids. Additionally, it may be possible to consider attaching a die, which is a different material, to the cavity, by utilizing a glass layer in which a cavity is preemptively formed in a chip-first manner, but since the glass layer is formed of a significantly brittle material, cracks may occur in the glass layer during a cavity formation process. On the other hand, the printed circuit board 100A according to an example embeds the heat dissipation member 151 capable of directly contacting glass without a micro gap in the glass layer 111. For example, the heat dissipation member 151 may be disposed in a casting mold and glass may be cast to implement a structure in which the heat dissipation member 151 is embedded in the glass layer 111. In this case, when embedding the heat dissipation member 151, cracks may be prevented from occurring in the glass layer 111. Additionally, the heat dissipation member 151 may be in direct contact with the glass layer 111 without a step portion or a micro gap, thereby achieving excellent heat dissipation.

Meanwhile, a material included in the glass layer 111 may be disposed between one or more of the first surface and the second surface of the glass layer 111 and the heat dissipation member 151. For example, the heat dissipation member 151 and the first surface may be in contact with each other, but the heat dissipation member 151 and the second surface may be spaced apart from each other, and the heat dissipation member 151 and the second surface may be in contact with each other, but the heat dissipation member 151 and the first surface may be spaced apart from each other, or the heat dissipation member 151 may be spaced apart from both the first surface and the second surface. Preferably, as the heat dissipation member 151 is spaced apart from both the first surface and the second surface of the glass layer 111, the material included in the glass layer 111 may be disposed between each of the first surface and the second surface of the glass layer 111 and the heat dissipation member 151. For example, the heat dissipation member 151 may be spaced apart from the first surface and the second surface of the glass layer 111, respectively, and the glass layer 111 may entirely surround the heat dissipation member 151, and the glass layer 111 and the heat dissipation member 151 may be in direct contact with each other. The heat dissipation member 151 may be embedded in the glass layer 111 in this manner, thereby easily implementing the technical effect described above.

Meanwhile, the heat dissipation member 151 may be made of a metal. In this case, the heat dissipation member 151 may be spaced apart from the through-via 131 and may be electrically insulated from the through-via 131. For example, the heat dissipation member 151 may be unrelated to a via for signal transmission. In an example, in first and second directional cross-sections, the heat dissipation member 151 may have a structure in which a length thereof in the first direction is longer than a length thereof in the second direction. For example, the heat dissipation member 151 may be a metal column structure penetrating through a portion of the glass layer 111 in a direction substantially the same as the first direction in the glass layer 111. There may be a plurality of heat dissipation members 151 of the metal column structure, which may be spaced apart from each other and may be embedded in the glass layer 111, respectively.

Hereinafter, components of the printed circuit board 100A according to an example embodiment will be described in more detail with reference to the drawings.

The glass layer 111 may include glass, which is an amorphous solid. The glass may include, for example, pure silicon dioxide (about 100% SiO₂), soda lime glass, borosilicate glass, and alumino-silicate glass. However, the present disclosure is not limited thereto, and alternative glass materials, such as fluorine glass, phosphate glass, and chalcogen glass, may also be used as materials of the glass layer 111. Additionally, other additives may be further included to form glass having specific physical properties. These additives may include not only calcium carbonate (e.g. lime) and sodium carbonate (e.g. soda), but also magnesium, calcium, manganese, aluminum, lead, boron, iron, chromium, potassium, sulfur, and antimony, and may include carbonates and/or oxides of these elements and other elements. Meanwhile, the glass layer 111 may be distinguished from an organic insulating material including glass fiber (Glass Fiber, Glass Cloth or Glass Fabric), such as Copper Clad Laminate (CCL), Prepreg (PPG), and the like. The glass layer 111 may be in the form of, for example, a glass plate.

Each of the first and second wiring layers 121 and 122 may include a metal. The metal may include copper (Cu), aluminum (Al), silver (Ag), tin (Sn), gold (Au), nickel (Ni), lead (Pb), titanium (Ti), and/or alloys thereof. For example, the first and second wiring layers 121 and 122 may include a titanium (Ti) layer and a copper (Cu) layer formed by sputtering, as a plurality of seed layers, and may include electrolytic copper formed by electrolytic plating as a pattern plating layer based thereon. However, the present disclosure is not limited thereto, and, if necessary, chemical copper formed by electroless plating may be included as a seed layer. The first and second wiring layers 121 and 122 may perform various functions according to the design. For example, the first and second wiring layers 121 and 122 may include signal patterns, power patterns, and ground patterns. These patterns may take various forms, such as a line, a trace, a plane, a pad, and a land. In an example, the first and second wiring layers 121 and 122 may be formed directly on the first surface and the second surface of the glass layer 111, respectively, but the present disclosure is not limited thereto. The first and second wiring layers 121 and 122 may be electrically connected to each other through a through-via 131. Additionally, the first and second wiring layers 121 and 122 may include various types of pattern structures not illustrated in the drawing, which may vary depending on the design.

The through-via 131 may include a metal. The metal may include copper (Cu), aluminum (Al), silver (Ag), tin (Sn), gold (Au), nickel (Ni), lead (Pb), titanium (Ti), and/or alloys thereof. For example, the through-via 131 may include a titanium (Ti) layer and a copper (Cu) layer formed by sputtering, as a plurality of seed layers, and may include electrolytic copper formed by electrolytic plating as a filled plating layer based thereon. However, the present disclosure is not limited thereto, and may include chemical copper formed by electroless plating as a seed layer if necessary. The through-via 131 may perform various functions depending on the design. For example, through-via 131 may include a signal via, a power via, and a ground via. If necessary, a length of the through-via 131 in the first direction may be relatively shorter than a length of the glass layer 111 in the first direction. For example, both ends of the through-via 131 in the first direction may be partially recessed as compared to the first and second surfaces of the glass layer 111. The through-via 131 may have a shape in which side surfaces thereof are vertical in the first and second directional cross-sections, but is not limited thereto, and may have a shape in which the side surfaces thereof are tapered, for example, may have an hourglass shape. The through-via 131 may connect at least portions of each of the first and second wiring layers 121 and 122 to each other. The through-via 131 may be a Through Glass Via (TGV). The through-via 131 may be provided in plural, and a plurality of through-vias 131 may be spaced apart from each other in the second direction.

Each of the first and second resist layers 141 and 142 may include an organic insulating material. The organic insulating material may include a thermosetting resin such as an epoxy resin, a thermoplastic resin such as a polyimide, or an inorganic filler and/or an organic filler together with the resin. For example, the organic insulating material may include Ajinomoto Build-up Film (ABF), Photoimageable Dielectric (PID), Solder Resist (SR), but the present disclosure is not limited to. Each of the first and second resist layers 141 and 142 may be formed of a plurality of layers. Each of the first and second resist layers 141 and 142 may have openings exposing the first and second wiring layers 121 and 122, and each of the openings may be provided in plural. The pad pattern exposed through the openings may be Solder Mask Defined (SMD) and/or Non Solder Mask Defined (NSMD).

The heat dissipation member 151 may include various materials that are easy to dissipate heat. The material of the heat dissipation member 151 may have a melting point higher than a melting point of the glass, for example, so as not to melt during the molding process of the glass. For example, the heat dissipation member 151 may include a metal, more specifically, copper (Cu), aluminum (Al), silver (Ag), tin (Sn), gold (Au), nickel (Ni), lead (Pb), titanium (Ti), and/or alloys thereof. Invar, or the like, may be used as the alloy. However, the present disclosure is not limited thereto, and the heat dissipation member 151 may include graphite, a polymeric thermally conductive material, or a heat dissipation tape, in addition to the metal. The heat dissipation member 151 may be spaced apart from the first surface and/or the second surface of the glass layer 111, and may be electrically insulated from the first and second wiring layers 121 and 122, and the through-via 131. In an example, the heat dissipation member 151 may have a metal column shape, and in this case, the metal column may have various shapes such as a cylindrical column and a polygonal column. If necessary, the heat dissipation member 151 may have a plate structure in which a predetermined length thereof in the third direction, for example, a length in the third direction, is longer than a length thereof in the second direction. The heat dissipation members 151 may be provided in plural, and each of the heat dissipation members 151 may be entirely surrounded by the glass layer 111. Additionally, the heat dissipation members 151 may be spaced apart from each other in the second direction and/or the third direction in the glass layer 111.

Meanwhile, if necessary, a build-up layer may be further disposed on the first surface and the second surface of the glass layer 111, and a build-up wiring layer may be further disposed on each build-up layer. Additionally, a build-up via layer may be further formed on the build-up layer. In this case, the first and second resist layers 141 and 142 may be disposed on the build-up layers on both sides in the first direction, respectively. Additionally, a frame having a through-hole may be further included, and in this case, the glass layer 111 may be disposed in the through-hole of the frame, and remaining space of the through-hole may be filled with a filler or a build-up layer. In this manner, the printed circuit board 100A according to an example embodiment may be applied to various structures and in various forms. Accordingly, the printed circuit board 100A may be applied as a package board. Additionally, the printed circuit board 100A may be easily applied to a large-area board for a server.

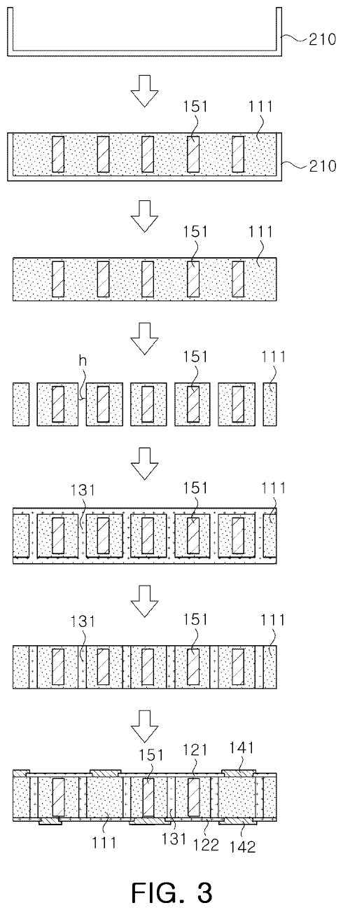

FIG. 3 is a process cross-sectional view schematically illustrating an example of manufacturing process for the printed circuit board of FIG. 2.

Referring to FIG. 3, a casting mold 210 may be prepared, a heat dissipation member 151 may be inserted into the casting mold 210, and glass may be cast into the casting mold 210 to form a glass layer 111 with the heat dissipation member 151 embedded therein. In this manner, since the casting process is used, cracks, or the like, may be prevented from occurring in the glass layer 111, and the glass layer 111 and the heat dissipation member 151 may be completely adhered without a fine gap or a step portion. Additionally, since the degree of freedom of the heat dissipation member 151 is high, there may be almost no structural restrictions. Additionally, since the heat dissipation member 151 does not come into contact with an organic insulating layer having low thermal conductivity, the heat dissipation characteristics may be further improved. Meanwhile, the glass layer 111 may surround an entire surface of the heat dissipation member 151. For example, in a state in which an upper side of the heat dissipation member 151 is fixed by a jig, a lower portion of the casting mold 210 may be cast with glass, and the jig may then be removed, and the heat dissipation member 151 may be embedded in the glass layer 111 in a manner in which the upper side of the heat dissipation member 151 is additionally cast with glass. Alternatively, the casting mold 210 itself may be made in a manner that may support the heat dissipation member 151 in a clamping manner, so that the glass layer 111 may surround the entire surface of the heat dissipation member 151.

Next, a through-hole h may be formed in the glass layer 111 using etching, blasting, laser, plasma, or the like, a seed layer may be formed on an entire exposed surface of the glass layer 111 by sputtering or electroless plating, a plating layer may be formed on the seed layer by electrolytic plating, and then annealing may be performed, and the plating layers on an upper surface and a lower surface of the glass layer 111 may be removed in a polishing process such as Chemical Mechanical Planarization (CMP), thereby forming a through-via 131 in the glass layer 111. Next, a seed layer may be formed on the glass layer 111 by sputtering or electroless plating, and a plating layer may be formed on the seed layer by electrolytic plating, thereby forming first and second wiring layers 121 and 122. If necessary, the seed layer and the plating layer disposed on the first surface and the second surface of the glass layer 111 may be directly patterned by etching, or the like, without a polishing process, thereby forming the first and second wiring layers 121 and 122. Then, first and second resist layers 141 and 142 may be formed in a lamination process or a coating process of an insulating material, and, if necessary, openings may be formed in the first and second resist layers 141 and 142. Through a series of processes, a printed circuit board 100A according to the above-described example may be manufactured, and the above-described content may be substantially identically applied to other descriptions.

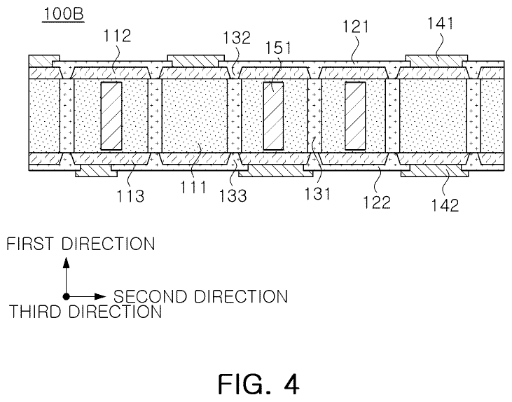

FIG. 4 is a cross-sectional view schematically illustrating a modified example of the printed circuit board of FIG. 2.

Referring to FIG. 4, a printed circuit board 100B according to a modified example embodiment may be configured so that a first insulating layer 112 may be disposed on a first surface of a glass layer 111, and a second insulating layer 113 may be disposed on a second surface of the glass layer 111 in the printed circuit board 100A according to the above-described example embodiment. A first wiring layer 121 may be disposed on the first insulating layer 112, a second wiring layer 122 may be disposed on the second insulating layer 113, a first resist layer 141 may be disposed on the first insulating layer 112, and a second resist layer 142 may be disposed on the second insulating layer 113. Additionally, the printed circuit board 100B according to a modified example embodiment may further include a first connection via 132 penetrating through the first insulating layer 112 and connecting at least a portion of the first wiring layer 121 to one side of the through-via 131, and a second connection via 133 penetrating through the second insulating layer 113 and connecting at least a portion of the second wiring layer 122 to the other side of the through-via 131. The first and second connection vias 132 and 133 may be directly connected to one side and the other side of the through-via 131, respectively.

In this manner, in the printed circuit board 100B, according to the modified example embodiment, the first and second wiring layers 121 and 122 may not be formed directly on the first and second surfaces of the glass layer 111 but rather on the additional first and second insulating layers 112 and 113. Additionally, the first and second wiring layers 121 and 122 may be directly connected to the through-via 131 via the first and second connection vias 132 and 133. In this case, the adhesion of the first and second wiring layers 121 and 122 may be improved by the first and second insulating layers 112 and 113, and the stress generated in the glass layer 111 may be reduced by these insulating layers.

Hereinafter, components of the printed circuit board 100B according to a modified example embodiment will be described in more detail with reference to the drawings.

Each of the first and second insulating layers 112 and 113 may include an organic insulating material. The organic insulating material may include a thermosetting resin such as an epoxy resin, a thermoplastic resin such as a polyimide, or an inorganic filler, an organic filler, and/or glass fiber (Glass Fiber, Glass Cloth or Glass Fabric) together with the resin. For example, the organic insulating material may be Prepreg (PPG), Ajinomoto Build-up Film (ABF), Photoimageable Dielectric (PID), but the present disclosure is not limited thereto. The first and second insulating layers 112 and 113 may include substantially the same insulating material, but are not limited thereto.

Each of the first and second connection vias 132 and 133 may include a metal. The metal may include copper (Cu), aluminum (Al), silver (Ag), tin (Sn), gold (Au), nickel (Ni), lead (Pb), titanium (Ti), and/or alloys thereof. For example, the first and second connection vias 132 and 133 may include chemical copper formed by electroless plating as a seed layer, and may include electrolytic copper formed by electrolytic plating based on the chemical copper, as a via plating layer. The first and second connection vias 132 and 133 may perform various functions according to the design. For example, the first and second connection vias 132 and 133 may include a signal via, a power via, and a ground via. Each of the first and second connection vias 132 and 133 may include a filled via in which a via hole is filled with a metal, but may also include a conformal via in which the metal is disposed along a wall surface of the via hole. The first and second connection vias 132 and 133 may have tapered shapes in opposite directions in the first and second directional cross-sections, respectively. Each of the first and second connection vias 132 and 133 may be provided in plural.

Meanwhile, if necessary, a build-up layer may be additionally disposed on each of the first insulating layer 112 and the second insulating layer 113, and a build-up wiring layer may be further disposed on each of the build-up layers. Additionally, a build-up via layer may be further formed on the build-up layer. In this case, each of the first and second resist layers 141 and 142 may be disposed on the build-up layers on both sides in the first direction. Additionally, a frame having a through-hole may be further included, in which case the glass layer 111 may be disposed within the through-hole of the frame, and a remaining space of the through-hole may be filled with a filler, the first insulating layer 112 or the second insulating layer 113. In this manner, the printed circuit board 100B according to the modified example embodiment may also be applied to various structures and in various forms. Accordingly, the printed circuit board 100B may be applied as a package board. Additionally, the printed circuit board 100B may be easily applied to a large-area board for a server. Additionally, the above-described content in the printed circuit board 100A according to an example embodiment and the manufacturing method thereof may be substantially identically applied to other descriptions.

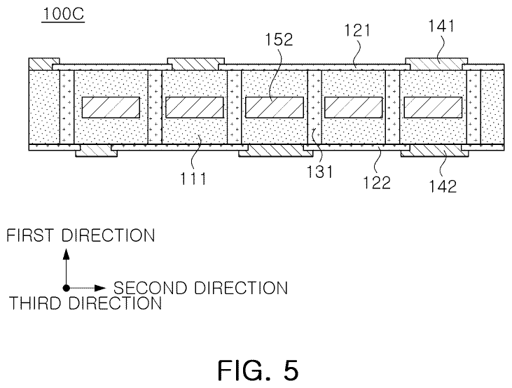

FIG. 5 is a cross-sectional view schematically illustrating another example of a printed circuit board.

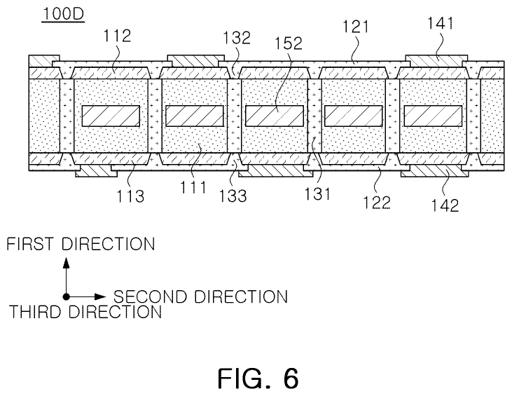

FIG. 6 is a cross-sectional view schematically illustrating a modified example of the printed circuit board shown in FIG. 5.

Referring to the drawings, a printed circuit board 100C according to another example embodiment and a printed circuit board 100D according to a modified example embodiment thereof may be configured so that the structure and arrangement of a heat dissipation member 152 embedded in a glass layer 111 may be changed, in the printed circuit board 100A according to the above-described example embodiment and the printed circuit board 100B according to the modified example embodiment thereof, respectively. For example, in another example embodiment and a modified example embodiment thereof, in the first and second directional cross-sections, the heat dissipation member 152 may have a structure in which a length thereof in the second direction is longer than a length thereof in the first direction. For example, the heat dissipation member 152 may have a metal plate structure disposed to have a substantially flat surface in a direction, substantially parallel to the second direction, in the glass layer 111. The metal plate structure may, for example, have lengths in the second direction and the third direction each longer than a length in the first direction. Additionally, both surfaces thereof may be substantially flat with respect to the first direction. The heat dissipation member 152 of the metal plate structure may be provided in plural, and a plurality of heat dissipation members 152 may be spaced apart from each other and may be embedded in the glass layer 111, respectively. In this case, the heat dissipation member 152 may be embedded in the glass layer 111 more stably.

Additionally, the above-described content in the printed circuit board 100A according to an example embodiment and the printed circuit board 100B according to a modified example embodiment thereof may be substantially identically applied to other descriptions. Additionally, in the described content of the manufacturing example of the printed circuit board 100A according to an example embodiment, a remaining content except for the structure and arrangement of the heat dissipation member 152 may be substantially identically applied thereto, and the manufacturing may be performed with reference thereto.

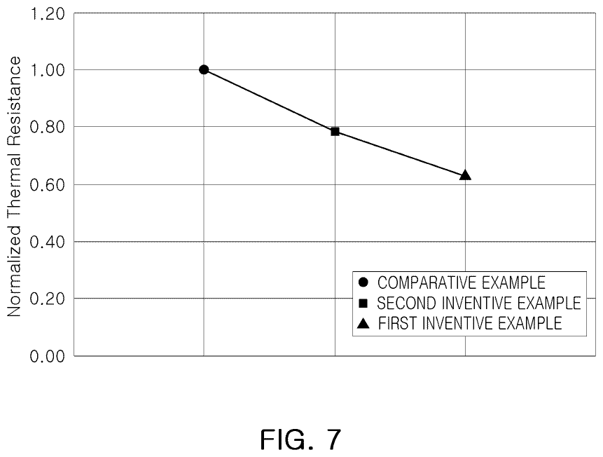

FIG. 7 is a graph schematically illustrating the heat dissipation effect of the printed circuit board shown in FIG. 2 and the printed circuit board shown in FIG. 5.

Referring to FIG. 7, a structure of Inventive Example 1 may be a structure of the printed circuit board 100A according to the above-described example embodiment in which the heat dissipation member 151 is embedded in the glass layer 111, a structure of Inventive Example 2 may be the structure of the printed circuit board 100C according to the above-described other example embodiment in which the heat dissipation member 152 is embedded in the glass layer 111, a structure of the comparative example may be a structure of the printed circuit board 100A according to the above-described example embodiment in which the heat dissipation member 151 is omitted. The thermal resistances of each of these structures in the first direction were compared and are illustrated in a graph. In the normalized thermal resistance, a thermal resistance value of the comparative example structure was used as a reference. It may be seen that the structures of Inventive Example 1 and Inventive Example 2 have relatively small thermal resistances in the first direction as compared to the comparative example structure. Accordingly, it may be seen that the structures of Inventive Example 1 and Inventive Example 2 have excellent heat dissipation effects.

In the present disclosure, the expression ‘covering’ may include a case of covering at least a portion as well as a case of covering the whole, and may also include a case of covering not only directly but also indirectly. Furthermore, the expression ‘filling’ may include not only a case of completely filling but also a case of at least partially filling, and may also include a case of approximately filling. For example, this may include a case in which some pores or voids exist. Additionally, the expression ‘surrounding’ may include not only a case of completely surrounding but also a case of partially surrounding and a case of approximately surrounding. Additionally, the expression ‘exposing’ may include not only completely exposing but also partially exposing, and exposing may mean exposing from the filling of the component. For example, exposing a pad by an opening may mean exposing the pad from a resist layer, and a surface treatment layer or the like may be further disposed on the exposed pad.

In the present disclosure, the placement of an object in a through-portion or through-hole may refer not only to cases where the object is fully contained within the through-portion or through-hole but also to cases where the object protrudes upward or downward in a cross-section. For example, when the object is positioned within the through-portion or through-hole in a planar view, its placement may be interpreted more broadly.

In the present disclosure, determination may be performed by including process errors, positional deviations, errors at the time of measurement, which may occur substantially in a manufacturing process. For example, substantially the same direction may include not only the completely same direction but also the approximately the same direction. Also, being substantially parallel may include not only a case of being completely parallel but also a case of being approximately parallel. Additionally, substantially flat may include not only a case of being completely flat but also a case of being approximately flat.

In the present disclosure, “the same insulating material” may refer not only to an identical insulating material but also to an insulating material of the same type. Accordingly, while the composition of the insulating material is substantially the same, specific composition ratios may vary slightly.

In the present disclosure, the meaning on the cross-section may refer to a cross-sectional shape when an object is cut vertically, or a cross-sectional shape when the object is viewed in a side-view. Furthermore, the meaning on a plane may refer to a planar shape when the object is horizontally cut, or a planar shape when the object is viewed in a top-view or a bottom-view.

In the present disclosure, for convenience, a lower side, a lower portion, and a lower surface are used to refer to a downward direction with respect to a cross-section of a drawing, and an upper side, an upper portion, and an upper surface are used to refer to an opposite direction thereof. However, this is a definition of direction for the convenience of explanation, and the scope of the claim is not specifically limited by the description of this direction, and the concept of upper/lower may be changed at any time.

In the present disclosure, a meaning of being connected is a concept including not only directly connected but also indirectly connected through an adhesive layer or the like. In addition, expressions such as first and second are used to distinguish one component from another, and do not limit the order and/or importance of the components. In some cases, a first component may be referred to as a second component without departing from the scope of rights, or similarly, the second component may be referred to as the first component.

In the present disclosure, a thickness, a width, a length, a depth, a line width, a gap, a pitch, a separation distance, surface roughness, and the like, may be measured using a scanning microscope, an optical microscope, or the like, based on a cross-section of a printed circuit board that has been polished or cut, respectively. The cut cross-section may be a vertical cross-section or a horizontal cross-section, and each value may be measured based on a required cut cross-section. For example, a width of an upper portion and/or a lower portion of a via may be measured on a cross-section that has been cut along a central axis of the via. In this case, when the value is not constant, the value may be determined as an average value of values measured at five arbitrary points.

The expression ‘example embodiment used in the present disclosure’ does not mean the same embodiment, and is provided to explain different unique characteristics. However, the example embodiments presented above do not preclude being implemented in combination with features of other example embodiments. For example, even if matters described in a particular example embodiment are not described in other example embodiments, they may be understood as explanations related to other example embodiments unless there is an explanation contrary to or contradictory to matters in other example embodiments.

The terms used in the present disclosure are intended solely to describe an example embodiment and are not meant to limit the present disclosure. In this context, singular terms include their plural forms unless explicitly stated otherwise.

What is claimed is:

1. A printed circuit board, comprising:
a glass layer having a first surface and a second surface opposing each other in a first direction;
a heat dissipation member embedded in the glass layer; and
a through-via extending through at least a portion of the glass layer between the first surface and the second surface,
wherein the heat dissipation member is spaced apart from one or more of the first surface and the second surface of the glass layer.

2. The printed circuit board according to claim 1,
wherein a material included in the glass layer is disposed between at least one of the first surface and the second surface of the glass layer and the heat dissipation member.

3. The printed circuit board according to claim 1,
wherein the heat dissipation member is spaced apart from each of the first surface and the second surface of the glass layer,
the glass layer entirely surrounds the heat dissipation member, and
the glass layer is in direct contact with the heat dissipation member.

4. The printed circuit board according to claim 1,
wherein the heat dissipation member comprises a metal,
the heat dissipation member is spaced apart from the through-via, and
the heat dissipation member is electrically insulated from the through-via.

5. The printed circuit board according to claim 1,
wherein in a cross-sectional plane defined by the first direction and a second direction, perpendicular to the first direction, the heat dissipation member has a length in the first direction longer than a length in the second direction.

6. The printed circuit board according to claim 5,
wherein the heat dissipation member comprises one or more metal pillars extending through a portion of the glass layer in a direction substantially parallel to the first direction in the glass layer.

7. The printed circuit board according to claim 1,
wherein in a cross-sectional plane defined by the first direction and a second direction, perpendicular to the first direction, the heat dissipation member has a length in the second direction longer than a length in the first direction.

8. The printed circuit board according to claim 7,
wherein the heat dissipation member comprises one or more metal plates disposed to have a substantially flat surface in a direction, substantially parallel to the second direction, in the glass layer.

9. The printed circuit board according to claim 1, further comprising:
a first wiring layer disposed on the first surface of the glass layer; and
a second wiring layer disposed on the second surface of the glass layer,
wherein the through-via connects at least portions of each of the first and second wiring layers.

10. The printed circuit board according to claim 9, further comprising:
a first resist layer disposed on the first surface of the glass layer, and covering at least a portion of the first wiring layer while leaving at least another portion exposed; and
a second resist layer disposed on the second surface of the glass layer, and covering at least a portion of the second wiring layer while leaving at least another portion exposed.

11. The printed circuit board according to claim 1, further comprising:
a first insulating layer disposed on the first surface of the glass layer;
a first wiring layer disposed on the first insulating layer;
a first connection via penetrating through the first insulating layer and connecting at least a portion of the first wiring layer to one side of the through-via;
a second insulating layer disposed on the second surface of the glass layer;
a second wiring layer disposed on the second insulating layer; and
a second connection via penetrating through the second insulating layer and connecting at least a portion of the second wiring layer to another side of the through-via,
wherein each of the first and second connection vias is directly connected to the through-via.

12. The printed circuit board according to claim 11, further comprising:
a first resist layer disposed on the first insulating layer, and covering at least a portion of the first wiring layer while leaving at least another portion exposed; and
a second resist layer disposed on the second insulating layer, and covering at least a portion of the second wiring layer while leaving at least another portion exposed.

13. A printed circuit board, comprising:
a glass layer having a first surface and a second surface opposing each other in a first direction;
a plurality of heat dissipation members respectively embedded in the glass layer, and having a length in a second direction, perpendicular to the first direction, longer than a length in the first direction, in a cross-sectional plane defined by the first direction and the second direction; and
a plurality of through-vias respectively extending through at least a portion of the glass layer between the first surface and the second surface, and spaced apart from the plurality of heat dissipation members.

14. The printed circuit board according to claim 13,
wherein each of the plurality of heat dissipation members comprises a metal plate embedded in the glass layer, and the metal plate has a substantially flat surface in a direction, substantially parallel to the second direction.

15. The printed circuit board according to claim 13, further comprising:
a first wiring layer disposed on the first surface of the glass layer; and
a second wiring layer disposed on the second surface of the glass layer,
wherein the plurality of through-vias electrically connect the first and second wiring layers.

16. The printed circuit board according to claim 13, further comprising:
a first insulating layer disposed on the first surface of the glass layer;
a first wiring layer disposed on the first insulating layer;
a plurality of first connection vias respectively penetrating through the first insulating layer and directly connecting at least a portion of the first wiring layer to one side of each of the plurality of through-vias;
a second insulating layer disposed on the second surface of the glass layer;
a second wiring layer disposed on the second insulating layer; and
a plurality of second connection vias respectively penetrating through the second insulating layer and directly connecting at least a portion of the second wiring layer to another side of each of the plurality of through-vias.

17. A printed circuit board, comprising:
a glass layer having a first surface and a second surface opposing each other along a first direction;
a heat dissipation member embedded in the glass layer;
a plurality of through-vias extending through at least a portion of the glass layer between the first surface and the second surface;
a build-up layer disposed on at least one of the first surface and the second surface of the glass layer; and
a build-up wiring layer disposed on the build-up layer, and
wherein the heat dissipation member is spaced apart from the through-vias.

18. The printed circuit board according to claim 17,
wherein a build-up via layer is formed on the build-up layer.

19. The printed circuit board according to claim 18,
further comprising a frame having a through-hole,
wherein the glass layer is disposed within the through-hole of the frame.
